(19) United States
(12) Patent Application Publication
(10) Pub. No.: US 2026/0208481 A1
(43) Pub. Date: Jul. 23, 2026

(54) MANUFACTURING SYSTEM AND MANUFACTURING METHOD OF DISPLAY PANEL

(71) Applicant: SAMSUNG DISPLAY CO., LTD., YONGIN-SI (KR)

(72) Inventor: SEUNGHWA JEONG, Yongin-si (KR)

(21) Appl. No.: 19/312,556

(22) Filed: Aug. 28, 2025

(30) Foreign Application Priority Data
Jan. 23, 2025 (KR) 10-2025-0010575

(51) Int. Cl. B41J 2/045; B41J 2/125; H10H 29/01; H10K 59/12; H10K 71/13

(52) U.S. Cl. CPC B41J 2/04535; B41J 2/0456; B41J 2/04576; B41J 2/125; H10H 29/012; H10H 29/0361; H10K 59/1201; H10K 71/135

(57) ABSTRACT

A display panel manufacturing system includes a stage supporting a display panel. A head unit includes nozzles dispensing primary ink onto each of pixels of the display panel. A sensor unit obtains height information of the primary ink dispensed onto each of the pixels. A control unit calculates the amount of ink to be compensated for each of the pixels after the dispensing of the primary ink based on the height information of the primary ink and to control opening and closing of the nozzles. The nozzles additionally dispense the compensating ink onto each of the pixels before the dispensed primary ink undergoes curing.

### CROSS-REFERENCE TO RELATED APPLICATIONS

This application claims priority under 35 U.S.C. § 119 to Korean Patent Application No. 10-2025-0010575, filed on Jan. 23, 2025 in the Korean Intellectual Property Office, the disclosure of which is hereby incorporated by reference in its entirety herein.

### 1. Technical Field

The present disclosure relates to a system for manufacturing a display panel and a method of manufacturing a display panel. Specifically, the present disclosure pertains to a system and a method for manufacturing a display panel that include nozzles for dispensing ink.

### 2. Discussion of Related Art

An inkjet printing device may serve as a display panel manufacturing system. An inkjet printing device is a type of equipment used in a manufacturing processes to dispense ink onto a substrate panel. Various sensor units are employed to acquire information regarding the ink dispensing area. The data sensed by the sensor unit is analyzed by software to compensate for the dispensed ink. Inkjet printing is widely used in the manufacturing of printed circuit boards, semiconductors, and display panels, where high-resolution ink dispensing is crucial for product reliability.

However, when ink is discharged through the nozzles of an inkjet head, variations occur among individual nozzles as well as across the entire set of nozzles, leading to inconsistencies in ink deposition. These variations may cause irregularities in the final display panel, resulting in color non-uniformity or streaking. For example, differences in the dispersion of ink droplets among pixels lead to inconsistencies in the total amount of ink deposited per pixel. Consequently, certain pixels may not receive sufficient ink to reach the desired height, leading to variations in the optical properties of the display panel and the occurrence of streaks in the displayed image.

Due to these issues, achieving high-resolution color representation in display panels becomes challenging. If these color non-uniformities are severe, the manufactured display panel may become unsuitable for use. Therefore, addressing the issue of ink dispersion variations caused by differences among nozzles is important for ensuring an efficient ink compensation process in inkjet printing.

### SUMMARY

The present disclosure aims to address the aforementioned issues by providing a display panel manufacturing apparatus and method for dispensing a uniform amount of ink with a

### CONSISTENT HEIGHT PER PIXEL.

The present disclosure focuses on ensuring that, before the dispensed ink undergoes a curing process, the ink height for each pixel is uniform. To achieve this, correction pixels are selected, and the amount of ink to be compensated is calculated. Based on this calculation, compensation is carried out so that ink is ultimately dispensed to achieve a uniform height across all pixels. Accordingly, an ultimate object of embodiments of the present disclosure is to manufacture high-resolution display panels.

According to an embodiment of the present disclosure, a display panel manufacturing system includes a stage supporting a display panel. A head unit includes nozzles dispensing primary ink onto each of pixels of the display panel. A sensor unit obtains height information of the primary ink dispensed onto each of the pixels. A control unit calculates the amount of ink to be compensated for each of the pixels after the dispensing of the primary ink based on the height information of the primary ink and to control opening and closing of the nozzles. The nozzles additionally dispense the compensating ink onto each of the pixels before the dispensed primary ink undergoes curing.

In an embodiment, the control unit may control at least one of the number of droplets, the size of droplets, and a volume of discharge of compensating ink based on the calculated amount of the compensating ink.

In an embodiment, the control unit may control the size of droplets using a voltage value applied to the head unit.

In an embodiment, the primary ink and the compensating ink may be dispensed for manufacturing a color filter or a light-emitting diode of the display panel.

In an embodiment, the sensor unit may include a line confocal sensor obtaining the height information of the primary ink dispensed onto each of the pixels.

In an embodiment, the control unit may calculate a height of deficient ink for each of the pixels based on a difference between the height information of the dispensed primary ink and a reference height in a compensation direction.

In an embodiment, the control unit may calculate the amount of compensating ink to be dispensed based on the height of the deficient ink for each of the pixels.

In an embodiment, the head unit may move in conjunction with the sensor unit while simultaneously performing a sensing operation.

In an embodiment, the control unit may store information on the opening and closing of the nozzles and the calculated amount of compensating ink to be dispensed after dispensing primary ink onto each of the pixels.

In an embodiment, the head unit may communicate with the control unit after dispensing primary ink onto each of the pixels and dispenses the compensating ink additionally based on the communication with the control unit.

In an embodiment, the control unit may include an analysis unit, a driver, and an equipment controller. The analysis unit may receive the height information of the primary ink from the sensor unit, calculates a compensation pattern and the amount of compensating ink to be dispensed, and transmits the calculated compensation pattern and the amount of compensating ink to be dispensed to the head unit. The driver may receive control information from the equipment controller and transmit movement and tilt information to the head unit. The equipment controller may provide the control information including speed and rotation control information to the driver.

In an embodiment, the analysis unit may generate the compensation pattern by calculating at least one of a number of ink droplets, droplet size, and a volume of ink to be dispensed for each of the pixels when the compensating ink is additionally dispensed onto each of the pixels.

In an embodiment, after the compensating ink is additionally dispensed onto each of the pixels, a height of the dispensed ink in each pixel may be uniform.

According to an embodiment of the present disclosure, a method of manufacturing a display panel including a plurality of pixels comprises dispensing primary ink onto a display panel using a head unit including nozzles; obtaining, using a sensor unit, height information of the primary ink dispensed onto each of the plurality of pixels in an area where the primary ink is dispensed by the head unit; calculating, using a control unit, an amount of compensating ink to be dispensed based on the height information of the dispensed primary ink; determining opening and closing of the nozzles for dispensing the compensating ink; and dispensing, using the nozzles, the compensating ink additional onto each of the plurality of pixels before the dispensed primary ink undergoes curing.

In an embodiment, the control unit may control at least one of a number of ink droplets, an ink droplet size, and a volume of ink to be dispensed based on the calculated amount of the compensating ink.

In an embodiment, the control unit may control the ink droplet size using a voltage value applied to the head unit.

In an embodiment, the primary ink and the compensating ink may be dispensed for manufacturing a color filter or a light-emitting diode of the display panel.

In an embodiment, the control unit may include an analysis unit, a driver, and an equipment controller. The analysis unit may receive the height information of the primary ink from the sensor unit, calculate a compensation pattern and the amount of compensating ink to be dispensed, and transmit the calculated information to the head unit. The driver may receive control information from the equipment controller and transmit movement and tilt information to the head unit. The equipment controller may provide the control information including speed and rotation control information to the driver.

In an embodiment, the analysis unit generates the compensation pattern by calculating at least one of a number of ink droplets, droplet size, and a volume of ink to be dispensed for each of the pixels, based on the height information of the dispensed primary ink, when the compensating ink is additionally dispensed onto each of the pixels.

In an embodiment, after the compensating ink is additionally dispensed onto each of the plurality of pixels, a height of the dispensed ink in each of the plurality of pixels may be uniform.

Due to the nature of inkjet printing, ink dispensing through nozzles can result in variations in dispersion across different pixels. These variations in ink discharge can lead to inconsistencies in the height of the dispensed ink for each of the pixels. Such inconsistencies contribute to color non-uniformity, which ultimately reduces the process reliability in display panel manufacturing.

The present disclosure effectively addresses this issue by compensating for ink dispersion variations before the dispensed primary ink undergoes curing. For example, additional ink is dispensed while the ink remains in a liquid state, thereby increasing compensation efficiency and reducing the occurrence of streaks or irregularities in color uniformity.

Nonetheless, the technical effects of the present disclosure are not limited to the aforementioned advantages. Various modifications and applications can be implemented without departing from the spirit and scope of the disclosure.

### BRIEF DESCRIPTION OF THE DRAWINGS

These and/or other features will become apparent and more readily appreciated from the following description of non-limiting embodiments, taken in conjunction with the accompanying drawings in which:

FIG. 1 is a cross-sectional view illustrating an example of a display panel to which the present disclosure is applied;

FIG. 2 is a perspective view illustrating an example of a system for manufacturing a display panel to which the present disclosure is applied;

FIG. 3 is a perspective view illustrating an example of a head unit and pixels to which the present disclosure is applied;

FIG. 4 is a plan view illustrating a head unit to which the present disclosure is applied;

FIG. 5 is a plan view illustrating a cell head units to which the present disclosure is applied;

FIG. 6 is a cross-sectional view illustrating a display panel with color filters fabricated through inkjet printing to which the present disclosure is applied;

FIG. 7 is a flow diagram illustrating a process of the present disclosure;

FIG. 8 is a perspective view illustrating an example of a fluid control integration unit to which the present disclosure is applied;

FIG. 9 is a block diagram illustrating a control unit in the system for manufacturing a display panel according to the present disclosure;

FIG. 10 is a graph illustrating an example of height information of ink measured through a sensor unit according to an embodiment of the present disclosure; and

FIG. 11 is a cross-sectional view illustrating an example of additional ink dispensing onto the display panel before an ink curing process according to the present disclosure.

### DETAILED DESCRIPTION OF EMBODIMENTS

References will now be made in detail to certain non-limiting embodiments, of which examples are illustrated in the accompanying drawings, where like reference numerals refer to like elements throughout. The embodiments may have a variety of forms and permutations, but embodiments of the present disclosure shall by no means be construed as being limited to the described embodiments. Rather, the present disclosure shall be construed to encompass all forms, permutations, equivalents and substitutes covered by the technical ideas and scope of the present disclosure. Accordingly, non-limiting embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not necessarily be limited to the thicknesses, ratios, dimensions, etc. illustrated in the drawings.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Terms such as “first” and “second” may be used in describing various elements, but the above elements shall not be restricted to the above terms. The above terms may be used only to distinguish one element from the other. For instance, the first element may be named the second element, and vice versa, without departing the scope of the present disclosure. Unless clearly used otherwise, any expressions in a singular form may include a meaning of a plural form. The term “and/or” shall include the combination of a plurality of listed items or any of the plurality of listed items.

In the present disclosure, terms such as “system,” “module,” “unit,” “part,” and “portion” may include, or may be implemented by, computer-related software, hardware, or a combination of software and hardware.

In the present disclosure, three directions are defined as a first direction (DR1), a second direction (DR2), and a third direction (DR3). In an embodiment, the first direction (DR1) and the second direction (DR2) are orthogonal to each other on the same plane, and the third direction (DR3) is perpendicular to both the first direction (DR1) and the second direction (DR2). However, embodiments of the present disclosure are not necessarily limited thereto and the first to third directions DR1 to DR3 may cross each other at various different angles.

In the display industry, inkjet printing may be commonly applied to the color filter positioned on top of an organic light-emitting diode (OLED) to implement colors. Color filters may be used to separate colors or filter light of a specific wavelength. However, the application of the inkjet printing technology is not necessarily limited to color filters; it may also be used for fabricating OLEDs, light-emitting diodes (LEDs), quantum-dot light-emitting diodes (QLEDs), and micro light-emitting diodes (MicroLEDs).

The present disclosure concerns a display panel manufacturing system and method in which compensating ink is additionally dispensed onto a display panel before a dispensed primary ink is cured using height information of the dispensed primary ink obtained from a sensor unit. By compensation for ink dispersion variations before the dispensed primary ink is cured, the system and method provide a uniform height of dispensed ink in a plurality of pixels with respect to a reference height and eliminates the need for separate measurement equipment or an additional inspection process. The system and method provides a uniform amount of ink in the plurality of pixels in an efficient manner to increase the quality of the manufactured display panel.

FIG. 1 is a cross-sectional view illustrating an example of a display panel to which inkjet printing technology is applied. Referring to FIG. 1, in an embodiment a display panel DP may include a substrate SS, a circuit layer CL, a light-emitting diode layer ELL, an encapsulation layer TFE, a color filter layer CF, and a light-blocking portion BM, which may be successively stacked in a third direction DR3.

The substrate SS may be formed of various materials such as glass, metal, or plastic. For example, in an embodiment, the substrate SS may be a flexible substrate.

The circuit layer CL may be disposed on (e.g., disposed directly thereon) the substrate SS and may function as a pixel circuit unit including transistors and capacitors. In an embodiment, the circuit layer CL may include a buffer layer, a semiconductor layer, a gate insulation layer, a conductive layer, an interlayer insulation layer, a circuit insulation layer, and a planarization layer.

The light-emitting diode layer ELL may be disposed on (e.g., disposed directly thereon) the circuit layer CL. The light-emitting diode layer ELL may include light-emitting diodes and a pixel defining layer.

In an embodiment, first to third light-emitting diodes LD1, LD2, LD3 may be disposed on the circuit layer CL and may each include an anode electrode AE, a hole control layer HL, an emission layer EML, an electron control layer EL, and a cathode electrode CE. In an embodiment, the anode electrode AE of each of the first to third light-emitting diodes LD1, LD2, LD3 may be electrically connected to a first electrode or a second electrode of a transistor disposed in the circuit layer CL.

The first light-emitting diode LD1, the second light-emitting diode LD2, and the third light-emitting diode LD3 may be configured to emit light of different wavelengths from their respective first to third emission layers EML1, EML2, EML3. For example, in an embodiment the first light-emitting diode LD1 may be configured to emit red light, the second light-emitting diode LD2 may be configured to emit green light, and the third light-emitting diode LD3 may be configured to emit blue light.

The hole control layer HL may be disposed on the anode electrode AE and may assist holes generated from the anode electrode AE to move.

The first to third emission layers EML1, EML2, EML3 may each be disposed on the hole control layer HL and may be configured to emit light. In an embodiment, the first to third emission layers EML1, EML2, EML3 may include organic light-emitting materials or quantum dots. Accordingly, the first to third light-emitting diodes LD1, LD2, LD3 may be organic light-emitting diodes (OLEDs) or quantum dot light-emitting diodes (QLEDs).

The electron control layer EL may be disposed on the emission layers EML1, EML2, EML3 and may assist in the movement of electrons generated from the cathode electrode CE.

The cathode electrode CE may be disposed on the electron control layer EL. The cathode electrode CE may have low resistance to facilitate current flow. Additionally, the cathode electrode CE may allow a portion of incident light to transmit while reflecting the remaining portion of the incident light.

The pixel defining layer PDL may be disposed on (e.g., disposed directly thereon) the circuit layer CL. The pixel defining layer PDL may define and separate individual pixels. The pixel defining layer PDL may include a first opening OP1 that exposes at least a portion of the anode electrode AE, such as a central portion of the anode electrode AE. The hole control layer HL may be disposed on the anode electrode AE exposed through the first opening OP1, and the first to third emission layers EML1, EML2, EML3 may be disposed on the hole control layer HL. The first to third emission layers EML1, EML2, EML3 may be positioned within the first opening OP1. The cathode electrode CE may be disposed on each of the first to third emission layers EML1, EML2, EML3. The cathode electrode CE may be disposed across the entire pixel defining layer PDL.

The encapsulation layer TFE may be disposed on the light-emitting diode layer ELL. The encapsulation layer TFE may be disposed on the cathode electrode CE. The encapsulation layer TFE may be configured to seal the first to third light-emitting diodes LD1, LD2, LD3 to protect the first to third light-emitting diodes LD1, LD2, LD3 from exposure to oxygen or moisture.

The light-blocking portion BM may be disposed on the encapsulation layer TFE. The light-blocking portion BM may include a material capable of blocking light. The light-blocking portion BM, along with the pixel defining layer PDL, may define and separate individual pixels and may include a second opening OP2 overlapping the first to third light-emitting diodes LD1, LD2, LD3.

The first to third color filters CF1, CF2, CF3 may be disposed within the second opening OP2 of the light-blocking portion BM. The first to third color filters CF1, CF2, CF3 may be spaced apart from each other and separated by the light-blocking portion BM. At least a portion of the first to third color filters CF1, CF2, CF3 may be disposed on the light-blocking portion BM to overlap the light-blocking portion BM.

The first to third color filters CF1, CF2, CF3 may be configured to filter the light emitted from the first to third light-emitting diodes LD1, LD2, LD3 before the light is externally transmitted. Additionally, the first to third color filters CF1, CF2, CF3 may be configured to reduce the reflectance of incident external light.

The first to third color filters CF1, CF2, CF3 may correspond to different colors corresponding to a light-emitting region of each pixel. For example, the first color filter CF1 may be configured to filter red light when the first light-emitting diode LD1 emits light. The second color filter CF2 may be configured to filter green light when the second light-emitting diode LD2 emits light. The third color filter CF3 may be configured to filter blue light when the third light-emitting diode LD3 emits light.

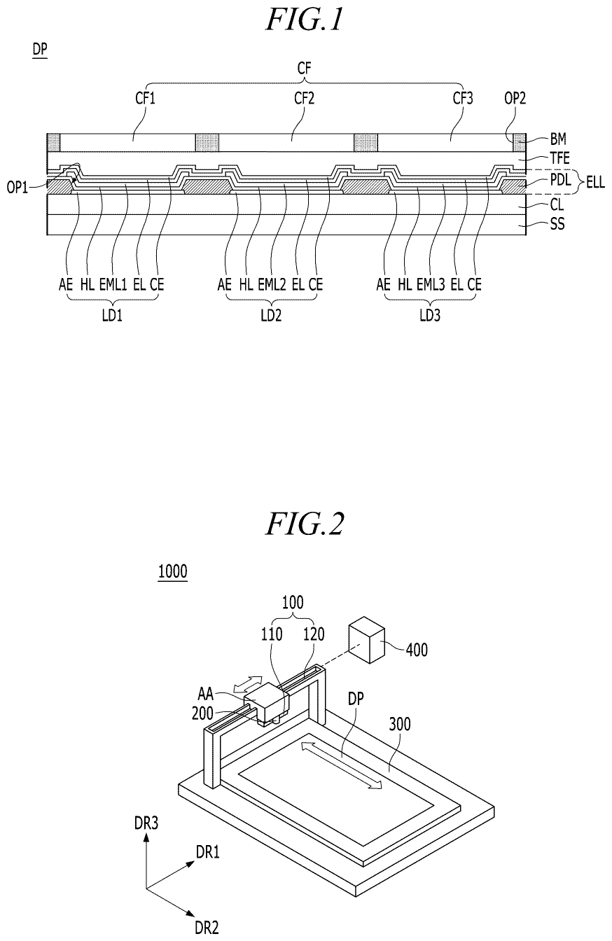

FIG. 2 is a perspective view illustrating an example of a display panel manufacturing system 1000 according to an embodiment of the present disclosure. While FIG. 2 illustrates the display panel manufacturing system 1000, embodiments of the present disclosure are not necessarily limited thereto and may also be applied to other types of panel manufacturing systems requiring ink dispensing. Referring to FIG. 2, in an embodiment the display panel manufacturing system 1000 may include a dispensing unit 100, a sensor unit 200, a stage 300 supporting the display panel DP, and a control unit 400.

In an embodiment, the dispensing unit 100 may include a head unit 110 and a movement unit 120 for dispensing ink. The head unit 110 may include a nozzle configured to dispense ink onto a display panel DP. The ink may be ejected in a liquid form through the nozzle and dispensed onto pixels PX of the display panel DP.

The movement unit 120 may be configured to move the head unit 110 relative to the display panel DP. As shown in FIG. 2, the movement unit 120 may be configured to move the head unit 110 in conjunction with the sensor unit 200 while a sensing operation is performed. The movement unit 120 may allow the head unit 110 to move in a horizontal direction, such as in a first direction DR1, in which case, the movement unit 120 may also move the display panel DP in a second direction DR2, which is perpendicular to the movement direction of the head unit 110, such as perpendicular to the first direction DR1.

Additionally, the movement unit 120 may allow the head unit 110 to move not only in the first direction DR1 but also in the horizontal second direction DR2. Alternatively, in an embodiment the movement unit 120 may allow the head unit 110 to move in the second direction DR2, while the stage 300 moves the display panel DP in the first direction DR1.

In an embodiment, the movement unit 120 may further be configured to move in a third direction DR3 for the purpose of adjusting the height of the head unit 110 relative to the display panel DP. Furthermore, the movement unit 120 may also be configured to perform rotational movement for the purpose of tilting the head unit 110 relative to the display panel DP. For example, the movement unit 120 may be configured to rotate the head unit 110 about a rotation axis in at least one of the first direction DR1 to the third direction DR3.

The display panel DP and the stage 300 may be positioned below the head unit 110. In an embodiment, the stage 300 may be configured to move and rotate similarly to the movement of the head unit 110 and the movement unit 120 when the head unit 110 and the movement unit 120 are fixed.

In an embodiment, the sensor unit 200 may be configured to measure various parameters, such as the distance or angle of a target position, the ink-dispensed area, and the height of the dispensed ink. In an embodiment, the sensor unit 200 may be configured with various types of sensors, such as a camera, a line confocal sensor, and a high-performance vision inspection sensor. The sensor unit 200 may be configured with a single sensor or a plurality of sensors. The position, type, and number of the sensor unit 200 applied in FIG. 2 is not necessarily limited thereto. For example, in some embodiments the position of the head unit 110 illustrated in the drawings may be modified. In an embodiment, the head unit 110 may be coupled with the sensor unit 200 and configured to move together with the sensor unit 200.

In an embodiment, the sensor unit 200 may be implemented as a vision inspection sensor. In an embodiment, the sensor unit 200 may be a non-contact three-dimensional (3D) measurement sensor, and more specifically, a line confocal sensor.

A line confocal sensor (LCI), which is a type of optical measurement technology capable of measuring 3D surface shapes at high resolution and high speed, is primarily used in manufacturing, semiconductor, display (including OLED), and precision machining industries. One of the key features of the line confocal sensor is its ability to measure a long line simultaneously instead of measuring a single point. This enables the line confocal sensor to cover a large area with a single scan, resulting in a significantly faster inspection.

Additionally, with the ability to detect light at a particular focal depth, the line confocal sensor provides a very shallow focal depth, allowing for high depth resolution. The line confocal sensor can extract surface topography and height information by analyzing the intensity of reflected light. Since the line confocal sensor operates in a non-contact manner, it can measure sensitive or fragile materials, such as OLED displays and wafers, without causing surface damage. Furthermore, the line confocal sensor can also measure transparent or semi-transparent materials, such as glass, metal, plastic, and silicon.

Line confocal sensors may be used for substrate flatness inspection, thin-film thickness measurement, panel alignment, and quality verification in the OLED and display manufacturing industries, for 3D shape measurement of wafers and defect inspection in the semiconductor industry, and for surface roughness analysis and microstructure inspection in the precision machining industry.

Line confocal sensors are optimized for high-precision inspection and real-time quality control in production lines and may provide a crucial role particularly in OLED display manufacturing processes. In an embodiment of the present disclosure, the line confocal sensor may be adapted for real-time measurement with high accuracy in high-speed production environments, with a typical sampling rate of 10 kHz or higher. However, high-resolution inkjet printing may require a high-specification sampling rate of 1 MHz, assuming a stage speed of 100 m/s and a pixel pitch of 0.096 mm (equivalent to 264 ppi). In application to high-resolution inkjet printing, the printing speed (e.g., stage speed) may be reduced or the sampling rate of the sensor may be increased when the sensor unit 200 is operated. Additionally, multiple line confocal sensors may be used to perform scanning and measurement to further enhance accuracy.

In an embodiment, the stage 300 may then be configured to stably hold the display panel DP so that ink dispensing can be performed without vibration during the ink dispensing process. In FIG. 2, the stage 300 is depicted to move in the second direction DR2 with respect to the head unit 110, in which case, the head unit 110 moves in the first direction DR1.

As shown in FIG. 2, the stage 300 may be formed as, but is not necessarily limited to, a generally rectangular flat surface so that the display panel DP can be placed on a top surface of the stage 300. The structure of the stage 300 may be implemented in various forms using a conventional industrial printer configuration or a combination thereof, depending on the implementation conditions.

The head unit 110 and the sensor unit 200 may together constitute the fluid control integration unit AA. In an embodiment, the sensor unit 200 may be configured to perform real-time measurement of ink dispensed onto the display panel DP through the nozzles of the head unit 110, and the opening and closing of the nozzles may be controlled accordingly to regulate ink dispensing. For example, the head unit and the sensor unit may be configured as a single assembly, and inkjet printing and measurement may be performed simultaneously.

The control unit 400 may be configured to manage, calculate, and control the overall operation of the display panel manufacturing system 1000. In an embodiment, the control unit 400 may be configured to control the display panel manufacturing system 1000 to calculate an ink dispensing height error (e.g., a deficiency or discrepancy) associated with the movement of the head unit 110 or the stage 300. Through the calculated compensation pattern, the control unit 400 may regulate the pattern of ink to be additionally dispensed. Based on this, before undergoing the curing process, the fluid control integration unit AA may dispense additional ink. In an embodiment, the main functions of the control unit 400 may include a task relating to generating control signals and transferring information, a task for calculating the amount of additional ink to be dispensed, a task for the determining the size of additional ink droplets, a task for controlling the size of ink droplets based on voltage values, and a task for storing the computed results and control signals.

The control unit 400 may be configured to calculate ink dispensing height errors (e.g., deficiencies or discrepancies) or control ink dispensing during the display panel manufacturing process by transferring information to or controlling the head unit 110, the movement unit 120, the sensor unit 200, and the stage 300. For example, in an embodiment the control unit 400 may be configured to control the movement unit 120 to move the head unit 110 in the first direction DR1. The control unit 400 may be configured to control the stage 300 to move the substrate in the second direction DR2. In an embodiment, the control unit 400 may be configured to control the opening and closing of the nozzles of the head unit 110 inside the fluid control integration unit AA to dispense ink onto the display panel DP. Additionally, the control unit 400 may be configured to control various sensor units for obtaining information on a region onto which ink is dispensed.

In an embodiment, the control unit 400 may be configured to receive information such as the height of ink for each pixel from the sensor unit 200 inside the fluid control integration unit AA. Based on the received information, software-based calculations for additional ink compensation pattern and ink dispensing height may be performed. In an embodiment, with the various information received from the sensor unit 200, an amount of the dispensing ink for a uniform height across all pixels may be calculated.

The control unit 400 may include a processor, a memory, and a storage for correcting the uniform height of the dispensed ink. In an embodiment, the sensor unit 200 may be configured to store the measured result value, which is the calculated height of the dispensed primary ink, received from the control unit 400. In an embodiment, the control unit 400 may be configured to then execute a compensation pattern calculation algorithm for additional ink dispensing.

Additional compensation pixel positions may refer to locations where additional ink dispensing is required to ensure that the RGB colors within every color filter maintain the same height as each other after correcting the dispensed primary ink height. The additional compensation pixel positions may be determined based on values measured by the sensor unit 200 and calculated using an algorithm configured to determine the amount of additional ink to be dispensed according to the insufficient ink height.

The compensation height may correspond to an error value between the desired ink-filled height and the actual dispensed ink height and may be related to the uniformity of display panel color. Based on the calculated ink height information, an ink compensation pattern algorithm may be executed for compensation. In an embodiment, the compensation pattern algorithm may be configured to determine the number of compensating ink droplets, the size of the compensating ink droplets, and a voltage value to be applied to the head unit, such as the nozzles, according to the ink droplet size.

In an embodiment, the control unit 400 may be configured to execute an algorithm stored in the storage using a processor to perform computational tasks such as calculations or algorithm-based software operations. However, the aforementioned calculations or algorithms are not necessarily limited to software implementation and may be realized using dedicated logic circuits.

The control unit 400 may be configured to receive information related to ink dispensing operations, such as the start and end of ink dispensing, and to execute ink dispensing accordingly. Through this process, the control unit 400 may be configured to automatically manage the ink dispensing equipment and enable the display panel manufacturing system 1000 to perform necessary tasks step by step. Additionally, the control unit 400 may include a display unit, such as a monitor, for displaying received input information or computation and calculation results.

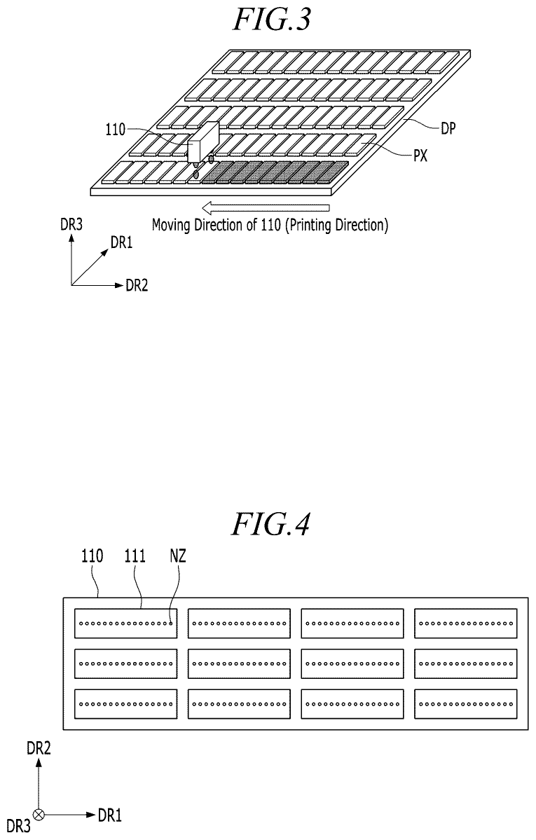

FIG. 3 is a perspective view illustrating an example of a head unit and pixels according to an embodiment of the present disclosure. For example, referring to FIG. 1, each pixel unit of a color filter in the OLED display panel DP may consist of three subpixels corresponding to RGB, and the RGB subpixels may be arranged in, but not necessarily limited to, a checkerboard pattern.

In an embodiment, each RGB subpixel may be formed by individually ejecting ink containing respective dyes or pigments from an inkjet printer head onto each subpixel. In an embodiment, the ink may be provided in a solution or colloidal state. For example, in an embodiment the solvent may be, but is not necessarily limited to, acetone, water, alcohol, toluene, propylene glycol (PG), or propylene glycol methyl acetate (PGMA).

Referring to FIGS. 3 and 4, the head unit 110 may include a cell head unit 111 (see FIG. 4) and a nozzle NZ (see FIG. 4) configured to dispense ink onto the substrate in a third direction DR3. The pixels PX are positioned on the display panel DP, and each pixel PX is aligned under a corresponding nozzle NZ of the cell head unit 111. For simplicity, FIG. 3 is illustrated as one of the pixels PX corresponding to the head unit 110, and there is a one-to-one correspondence between the nozzles NZ and the pixels PX. But the configuration is not necessarily limited to a one-to-one arrangement. Additionally, the spacing between the nozzles and the spacing between the pixels may be the same. However, embodiments of the present disclosure are not necessarily limited thereto.

In an embodiment, while each pixel PX is illustrated as having a rectangular shape in FIG. 3, the pixels PX of the display panel DP are not necessarily limited to this shape and may be formed in various different shapes. Ink is dispensed into and filled in these pixels PX by inkjet printing. Furthermore, the unit ejection interval of the nozzles NZ may vary depending on the resolution to be implemented, such as pixels per inch (ppi).

FIG. 4 is a plan view illustrating an example of the head unit 110 according to an embodiment of the present disclosure. Referring to FIG. 4, in an embodiment the head unit 110 may include the cell head unit 111, which may include the nozzles NZ. The head unit 110 may be configured with a plurality of cell head units 111. However, the structure of the cell head unit 111 is not necessarily limited to the configuration illustrated in FIG. 4. The cell head unit 111 may include a plurality of nozzles NZ configured for dispensing ink onto the substrate. In an embodiment, as the nozzles NZ are configured to dispense ink onto the display panel DP, the nozzles NZ may be arranged in the first direction DR1.

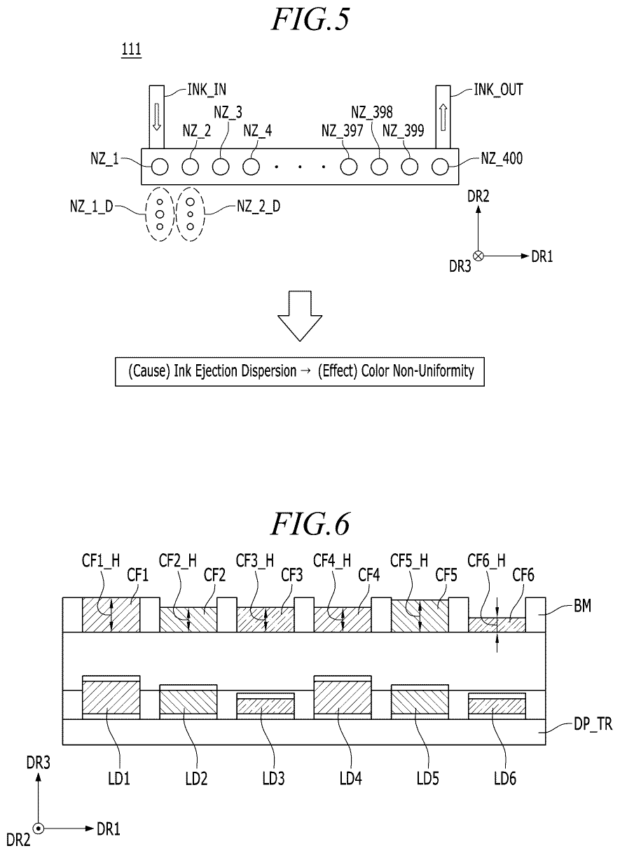

FIG. 5 is a plan view illustrating one of the cell head units 111 shown in FIG. 4. In an embodiment, the cell head unit 111 may include 400 nozzles NZ. However, the number of nozzles is merely an example and is not necessarily limited thereto. Each nozzle NZ may be configured to dispense a different amount of ink each time it opens and closes. For example, each nozzle NZ may be configured to dispense ink with a different dispersion. In other words, the 400 nozzles NZ may each be configured to dispense ink with varying dispersion characteristics.

Ultimately, when the 400 nozzles NZ dispense ink under the same conditions for N iterations, N being a natural number, the overall ink dispersion may still vary among the nozzles. Such variations in ink ejection may affect the uniformity of colors on the display panel and may result in visible color non-uniformity.

Since each of the 400 nozzles exhibits ejection dispersion, even if pre-correction is made for each nozzle NZ using a drive per nozzle (DPN) technique to reduce the dispersion, a dispersion level in a range of about 3% to about 5% may still occur. Additionally, the higher the resolution of the nozzles is in the head unit 110, the more pronounced the dispersion may become. Furthermore, pre-calibrated DPN values may change over time, and ink ejection dispersion may also be influenced by factors such as the ejection volume of an ink supply/discharge unit and the nozzle arrangement position, such as a central area.

Due to the nature of inkjet printing, each nozzle may exhibit ink ejection dispersion, and, in addition, the total ink ejection amount from all nozzles may also exhibit overall dispersion. Therefore, not only does each nozzle NZ have its own ejection dispersion, but the cumulative effect of all nozzles may also lead to inconsistencies in the final ink deposition height. The resulting variations in ink thickness may ultimately contribute to visible color non-Uniformity on the display panel DP.

FIG. 6 is a cross-sectional view illustrating variations in ink height dispensed onto the display panel DP, and more specifically, onto the color filters, due to differences in ink dispersion among the nozzles, as described in FIG. 5, while the head unit 110 moves. For example, due to the dispersion differences of ink dispensed from the nozzles NZ described in FIG. 5, the ink height may vary for each of the color filters.

FIG. 6 illustrates the display panel DP where ink is dispensed onto the color filters, as described in FIG. 1. Referring to FIG. 3, when the nozzles NZ are moved by the movement of the head unit 110 at regular intervals in the first direction DR1, variations in ink height may occur due to ink dispersion along the first direction DR1. This means that when ink is dispensed from the nozzles NZ of the head unit 110, dispersion of the dispensed ink in the first direction DR1 may cause height differences in the dispensed ink droplets.

Referring to FIG. 6, the heights of ink dispensed into each of the first to sixth color filters CF1, CF2, CF3, CF4, CF5, CF6 are represented as CF1_H, CF2_H, CF3_H, CF4_H, CF5_H, and CF6_H, respectively. When compared with the height of the light-blocking portion BM, it can be observed that CF6_H has the least amount of dispensed ink. However, the height of the light-blocking portion BM is not always the reference point, but in this specification, as an embodiment, the final target height of the dispensed ink may be based on the height of the light-blocking portion BM. Thus, in an embodiment, the height of the light-blocking portion BM may be regarded as the intended reference height, assuming that the ink is dispensed with similar dispersion from each nozzle NZ. In an embodiment, to compensate for these variations in ink ejection, the control unit 400 may be configured to calculate the deficient ink height relative to the target reference height and, based on this calculation, determine and dispense an additional amount of ink for compensation.

Conventionally, in comparative embodiments, once the ink is dispensed with such variations in height and dispersion, the display panel DP undergoes a curing process. For example, after inkjet printing, it is common to proceed with post-printing processes such as curing, drying, or baking, followed by a thin-film measurement inspection step. If defects such as color non-uniformity are detected during inspection, the formed film may need to be removed and reprinted, which results in inefficiencies in the manufacturing process, as well as increased costs and time consumption.

Once the ink has been cured, the display panel DP can be inspected using equipment capable of inspecting the ink layer to verify whether the color filters are correctly formed. However, as previously described, correcting the cured ink layer can be inefficient; removing the hardened ink and re-dispensing ink is not a simple process and may be time consuming and expensive to perform.

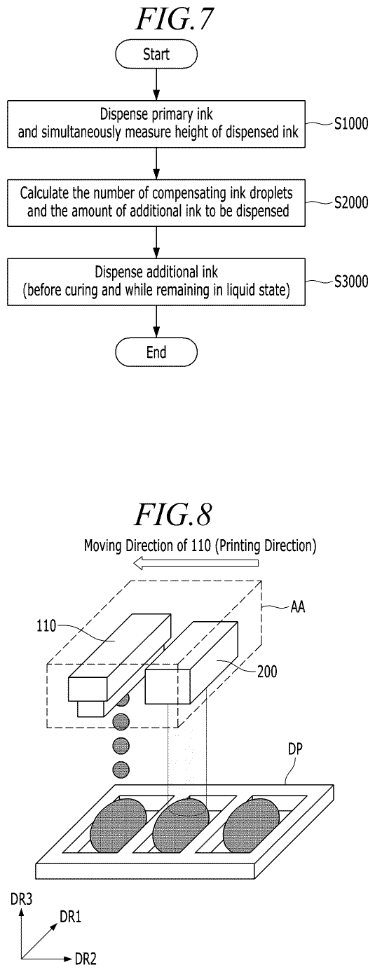

To address this issue, embodiments of the present disclosure propose the process illustrated in FIG. 7. In this method, additional ink dispensing is performed within the inkjet printing system itself, eliminating the need for additional measurement equipment or a separate inspection step that requires glass panel transfer. In an embodiment, the additional ink compensation for individual pixels is performed before curing, drying, or baking of the primary ink initially dispensed, ensuring that the compensation occurs while the primary ink is still in a liquid state.

FIG. 7 is a flow diagram illustrating a method for dispensing ink for each pixel of the color filter according to an embodiment of the present disclosure. Referring to FIG. 7, in an embodiment the method may include: dispensing primary ink and simultaneously measuring a height of the dispensed ink in block S1000, calculating the number of compensating ink droplets and the amount of additional ink to be dispensed in block S2000, and dispensing additional ink while the dispensed primary ink remains in a liquid state before undergoing curing in block S3000. However, embodiments of the present disclosure are not necessarily limited thereto and the method for dispensing ink on the display panel DP may include dispensing the ink on the light-emitting diode in some embodiments.

In step S1000, the head unit 110 may be moved using the fluid control integration unit AA, in which both the head unit and the sensor unit are integrated. This step may involve dispensing the primary ink for printing and measuring the height of the primary ink dispensed onto the display panel DP in real time. In some embodiments, the measurement is not made in real time, and the measurement may be made in a batch process after the primary ink is dispensed. During this step, measurement data, including the height of the primary ink dispensed onto the display panel DP, may be acquired.

In step S2000, the height information of the primary ink dispensed onto the display panel DP may be measured by the sensor unit 200 and transferred to the control unit 400 to accurately determine the ink height. In an embodiment, this step may involve detecting primary ink dispensing coordinates and an ink height difference for each pixel and calculating a compensation pattern for additional ink in the correction direction. For example, the correction direction (e.g., a compensation direction) may be the third direction DR3 which is based on a comparison of the primary ink height with respect to the reference height, such as the height of the blocking portion BM. In an embodiment, the calculated compensation pattern may include the number of compensating ink droplets in the compensation pattern, the droplet size for the compensation pattern, and the amount of (e.g., a volume of) additional ink to be dispensed for the compensation pattern. In an embodiment, the droplet size may be controlled based on voltage applied to the head unit, such as the nozzles. Information related to the amount of additional compensating ink to be dispensed may be stored in the control unit 400.

In step S3000, before the ink proceeds to the curing process, ink is additionally dispensed in a liquid state for additional printing based on the compensation pattern determined in step S2000. Therefore, additional ink is dispensed onto pixels requiring compensation in accordance with the compensation pattern determined in step S2000.

FIG. 8 is a perspective view illustrating the fluid control integration unit AA, in which the head unit and the sensor unit are integrated, moving and dispensing ink droplets onto the display panel and performing sensing and measurement to obtain the height of the dispensed ink. The fluid control integration unit AA, in which the sensor unit is integrated next to the head unit, is shown measuring the height information of the dispensed ink in real time. This process may be performed when dispensing the primary ink as well as when dispensing the additional ink.

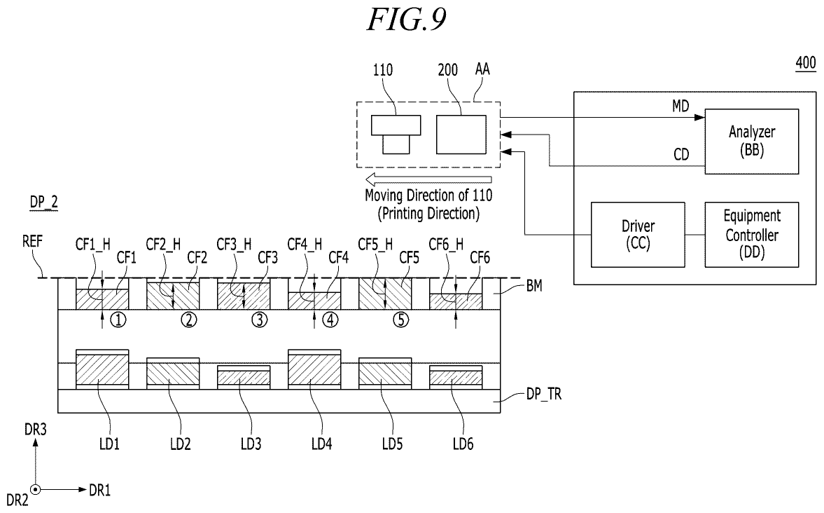

FIG. 9 is a block diagram illustrating the control unit 400 in display panel manufacturing system 1000. The fluid control integration unit AA may transmit the height information of the dispensed ink, measured in FIG. 8, to the control unit 400. Referring to FIG. 9, in an embodiment the control unit 400 may include sub-blocks such as an analyzer BB (e.g., an analysis unit), a driver CC, and an equipment controller DD. The analyzer BB may be configured to receive measurement data from the fluid control integration unit AA and transmit compensation ink information. The analyzer BB may be configured to acquire the height information of the dispensed ink (e.g., the dispensed primary ink) measured by the sensor unit 200 and calculate a compensation pattern to compensate for deficient ink dispensing. The compensation pattern may include the locations of pixels having insufficient ink dispensed and the calculated amount of additional ink to be dispensed. In an embodiment, the amount of additional ink to be dispensed may be determined based on the number of ink droplets, ink droplet size, and voltage-based control of the ink droplet size to compensate for the deficient ink volume. The compensation data calculated by the analyzer BB may be transmitted to the fluid control integration unit AA.

The driver CC may be configured to transmit movement and/or tilt information for any one of the head unit 110 and the stage 300 to the fluid control integration unit AA when opening and closing the nozzles. The equipment controller DD may be configured to provide the driver CC with information (e.g., control information) and conditions necessary for controlling speed and/or rotation of any one of the head unit and the stage when opening and closing the nozzles.

In an embodiment, as the head unit 110 moves, the data measured by the sensor unit 200 may be simultaneously input to the analyzer BB. Based on this data, the control unit 400 may detect height differences in the dispensed ink and calculate a compensation pattern for additional ink to be dispensed. While the compensation pattern may be determined based on the number of ink droplets, droplet size, and dispensing volume, some of the additional ink dispensing volume may be adjusted by controlling the ink droplet size through voltage applied to the head unit 110, such as the nozzles. For example, after having dispensed the primary ink and obtaining height data of the ink dispensed from all nozzles, the control unit 400 may calculate the deficient ink dispensing volume for all relevant pixels. The control unit 400 may store information on the opening and closing of the nozzles and the calculated amount of compensating ink to be dispensed after the dispensing of the primary ink onto each of the pixels.

Before proceeding to the curing process, additional ink may be dispensed onto pixels identified as having insufficient ink. In an embodiment, moving to the deficient pixels may follow the same method as dispensing the primary ink, but the nozzles may be selectively opened only for pixels requiring additional ink dispensing, and the nozzles may be directly moved to the pixels requiring additional ink dispensing. For example, the head unit may communicate with the control unit 400 after dispensing the primary ink onto each of the pixels and dispenses the compensating ink based on the communication with the control unit. It shall be appreciated that the movement of the nozzles for additional ink compensation is not necessarily limited to any single method. In an embodiment, regardless of the RGB color used in the color filter, all dispensed ink heights may be adjusted to match the height of the light-blocking portion BM (for illustrative understanding), though the reference height may not necessarily be limited to this.

In an embodiment, by enabling real-time measurement of the ink dispensing height for each pixel using a sensor connected to the head module, the total amount of ink dispensed onto each pixel can be determined. This information may be transmitted in real time to a compensation pattern program of the control unit 400, which may generate a compensation pattern accordingly.

Immediately after the primary inkjet printing process is completed, the additional inkjet printing may be performed based on the generated compensation pattern prior to the primary ink curing. As a result, all pixels may be uniformly filled, completing the inkjet printing process. Conventional inkjet measurement methods typically inspect the overall uniformity of the panel after printing. For example, they do not provide the ability to determine the ink dispensing amount for each pixel. Furthermore, changes in the ink ejection volume of the nozzles NZ over time cannot be fully controlled by pre-calibrated drive-per-nozzle (DPN) control methods. Even if the total ejection volume of all nozzles in the head unit is controlled using DPN, each nozzle NZ still exhibits ejection dispersion, making precise control of ink dispensing volume challenging.

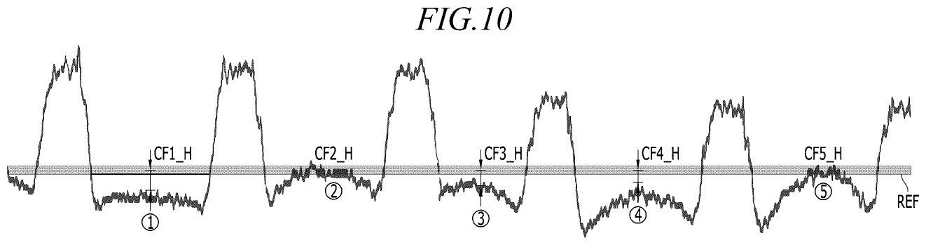

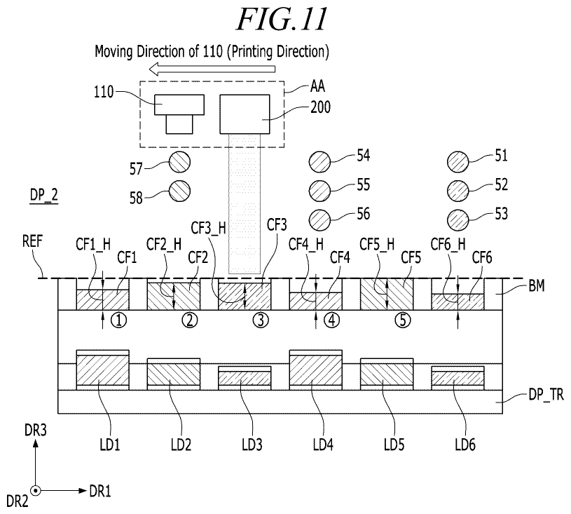

FIG. 10 is a graph illustrating an example of the height information including data from measuring the height of ink dispensed onto the display panel using a line confocal sensor, which is a non-contact three-dimensional (3D) measurement device, according to an embodiment. The measurement data shown in FIG. 10 includes the height information of the dispensed primary ink, as depicted in FIG. 9. Referring to FIG. 9, in a display panel DP_2, the first, third, and fourth color filters are shown to have dispensed ink with heights lower than the desired reference height (e.g., assuming the reference height is the light-blocking portion BM). The sensor unit 200 may be configured to measure the heights of the dispensed ink and transmit the measured data to the control unit 400.

FIG. 11 is a cross-sectional view illustrating additional compensating ink dispensing based on the height information of the dispensed ink obtained by the sensor unit 200 before the ink undergoes curing. In an embodiment, to additionally compensate ink onto pixel locations where the dispensed primary ink volume is determined to be insufficient through the analyzer BB, the driver CC, and the equipment controller DD of the control unit 400 shown in FIG. 9, the fluid control integration unit AA may communicate with the control unit 400 and calculate and execute the compensation pattern.

As shown in FIG. 10, the ink heights measured at the first, third, and fourth color filters are lower than the target height. For example, as shown in FIG. 8 and FIG. 9, in an embodiment an inline measurement module is integrated into the inkjet head, and pixel measurement is made simultaneously with ink dispensing. Information about the amount of ink dispensed for each pixel is transmitted to the inkjet pattern software of the analyzer BB within the control unit 400. Based on the received pixel data, the inkjet pattern software performs the tasks of: (1) identifying pixels requiring additional printing; (2) determine the number of ink droplets and the amount of additional ink to be dispensed (e.g., in FIG. 11, to compensate for the ink in the fourth color filter, additional ink is dispensed based on the height difference between the light-blocking portion BM and the dispensed ink height CF4_H); and (3) generating a compensation pattern. Immediately after the primary inkjet printing is completed, additional printing is performed based on the generated compensation pattern.

Referring to FIG. 11, the additional ink droplets dispensed into the fourth color filter are represented as droplets represented with reference numerals 54, 55, and 56. Although FIG. 11 illustrates three ink droplets, the actual number of ink droplets may be determined based on calculations performed by the analyzer BB. Additionally, the size of the ink droplets may be controlled based on voltage values applied to the head unit, such as the nozzles, and this control may also be analyzed and calculated by the analyzer BB of the control unit 400. However, since the additional ink droplets dispensed for compensation may also exhibit dispersion, they may not always be controlled with uniform dispersion. While the example assumes a single compensation, the number of compensation is not necessarily limited thereto.

The present disclosure enables additional ink compensation within the inkjet printing system itself, eliminating the need for separate measurement equipment or an additional inspection process requiring glass panel transfer. As a result, ink compensation may be performed efficiently, thereby reducing ink dispersion variations through the nozzles. Ultimately, this may prevent color non-uniformity on the display panel DP.

Hitherto, certain non-limiting embodiments of the present disclosure have been described above, but these are merely examples and are not intended to limit embodiments of the present disclosure. Those skilled in the art to which the present disclosure pertains may make various modifications and changes to the described embodiments by adding, changing, deleting, or adding certain elements, without departing from the scope of the technical ideas of the present disclosure, and such modifications and changes should also be regarded as being within the scope of the present disclosure.

What is claimed is:

1. A display panel manufacturing system, comprising:
a stage supporting a display panel;
a head unit comprising nozzles dispensing primary ink onto each of pixels of the display panel;
a sensor unit obtaining height information of the primary ink dispensed onto each of the pixels; and
a control unit calculating an amount of compensating ink to be dispensed onto each of the pixels after the dispensing of the primary ink based on the height information of the primary ink and control an opening and closing of the nozzles,
wherein the nozzles additionally dispense the compensating ink onto each of the pixels before the dispensed primary ink undergoes curing.

2. The display panel manufacturing system of claim 1, wherein the control unit controls at least one of a number of ink droplets, an ink droplet size, and a volume of the compensating ink based on the calculated amount of compensating ink.

3. The display panel manufacturing system of claim 2, wherein the control unit controls the ink droplet size using a voltage value applied to the head unit.

4. The display panel manufacturing system of claim 1, wherein the primary ink and the compensating ink are dispensed for manufacturing a color filter or a light-emitting diode of the display panel.

5. The display panel manufacturing system of claim 1, wherein the sensor unit comprises a line confocal sensor obtaining the height information of the primary ink dispensed onto each of the pixels.

6. The display panel manufacturing system of claim 1, wherein the control unit calculates a deficient ink height for each of the pixels based on a difference between the height information of the dispensed primary ink and a reference height in a compensation direction.

7. The display panel manufacturing system of claim 6, wherein the control unit calculates the amount of compensating ink to be dispensed based on the deficient ink height for each of the pixels.

8. The display panel manufacturing system of claim 1, wherein the head unit moves in conjunction with the sensor unit while performing a sensing operation.

9. The display panel manufacturing system of claim 8, wherein the control unit stores information on the opening and closing of the nozzles and the calculated amount of compensating ink to be dispensed after dispensing primary ink onto each of the pixels.

10. The display panel manufacturing system of claim 8, wherein the head unit communicates with the control unit after dispensing primary ink onto each of the pixels; and
dispenses the compensating ink additionally based on the communication with the control unit.

11. The display panel manufacturing system of claim 1, wherein the control unit comprises an analysis unit, a driver, and an equipment controller,
wherein the analysis unit receives the height information of the primary ink from the sensor unit, calculates a compensation pattern and the amount of compensating ink to be dispensed, and transmits the calculated compensation pattern and the amount of compensating ink to be dispensed to the head unit,
wherein the driver receives control information from the equipment controller and transmits movement and tilt information to the head unit, and
wherein the equipment controller provides the control information including speed and rotation control information to the driver.

12. The display panel manufacturing system of claim 11, wherein the analysis unit generates the compensation pattern by calculating at least one of a number of ink droplets, a droplet size, and a volume of ink to be dispensed for each of the pixels when dispensing the compensating ink additionally onto each of the pixels.

13. The display panel manufacturing system of claim 1, wherein, after the compensating ink is additionally dispensed onto each of the pixels, a height of the dispensed ink in each of the pixels is uniform.

14. A method of manufacturing a display panel including a plurality of pixels, the method comprising:
dispensing primary ink onto a display panel using a head unit comprising nozzles;
obtaining, using a sensor unit, height information of the primary ink dispensed onto each of the plurality of pixels in an area where the primary ink is dispensed by the head unit;
calculating, using a control unit, an amount of compensating ink to be dispensed based on the height information of the dispensed primary ink;
determining opening and closing of the nozzles for dispensing the compensating ink; and
dispensing, using the nozzles, the compensating ink additionally onto each of the plurality of pixels before the dispensed primary ink undergoes curing.

15. The method of manufacturing a display panel of claim 14, wherein the control unit controls at least one of a number of ink droplets, an ink droplet size, and a volume of ink to be dispensed based on the calculated amount of compensating ink.

16. The method of manufacturing a display panel of claim 15, wherein the control unit controls the ink droplet size using a voltage value applied to the head unit.

17. The method of manufacturing a display panel of claim 14, wherein the primary ink and the compensating ink are dispensed for manufacturing a color filter or a light-emitting diode of the display panel.

18. The method of manufacturing a display panel of claim 14, wherein the control unit comprises an analysis unit, a driver, and an equipment controller,
wherein the analysis unit receives the height information of the primary ink from the sensor unit, calculates a compensation pattern and the amount of compensating ink to be dispensed, and transmits the calculated information to the head unit,
wherein the driver receives control information from the equipment controller and transmits movement and tilt information to the head unit, and
wherein the equipment controller provides the control information including speed and rotation control information to the driver.

19. The method of manufacturing a display panel of claim 18, wherein the analysis unit generates the compensation pattern by calculating at least one of a number of ink droplets, a droplet size, and a volume of ink to be dispensed for each of the pixels, based on the height information of the dispensed primary ink, when dispensing the compensating ink additionally onto each of the pixels.

20. The method of manufacturing a display panel of claim 14, wherein, after the compensating ink is additionally dispensed onto each of the plurality pixels, a height of the dispensed ink in each of the plurality of pixels is uniform.
